(19) United States
(12) Patent Application Publication
(10) Pub. No.: US 2008/0173981 A1
(43) Pub. Date: Jul. 24, 2008

(54) INTEGRATED CIRCUIT (IC) CHIP WITH ONE OR MORE VERTICAL PLATE CAPACITORS AND METHOD OF MAKING THE CAPACITORS

(76) Inventors: Anil K. Chinthakindi, Poughkeepsie, NY (US); Douglas D. Coolbaugh, Essex Junction, VT (US); Ebenezer E. Eshun, Essex Junction, VT (US); Zhong-Xiang He, Essex Junction, VT (US); Anthony K. Stamper, Williston, VT (US); Kunal Vaed, Poughkeepsie, NY (US)

Correspondence Address: LAW OFFICE OF CHARLES W. PETERSON, JR. BURLINGTON, 435B Carlisle Dr., Herndon, VA, 20170, US

(21) Appl. No.: 11/624,712

(22) Filed: Jan. 19, 2007

(51) Int. Cl. H01L 27/06; H01L 21/02

(52) U.S. Cl. 257/535; 438/396; 257/E27.025; 257/E21.011

(57) ABSTRACT

An Integrated Circuit (IC) chip with one or more vertical plate capacitors, each vertical plate capacitor connected to circuits on the IC chip and a method of making the chip capacitors. The vertical plate capacitors are formed with base plate pattern (e.g., damascene copper) on a circuit layer and at least one upper plate layer (e.g., dual damascene copper) above, connected to and substantially identical with the base plate pattern. A vertical pair of capacitor plates are formed by the plate layer and base plate. Capacitor dielectric between the vertical pair of capacitor plates is, at least in part, a high-k dielectric.

### BACKGROUND OF THE INVENTION

1. Field of the Invention

The present invention is related to on-chip capacitors for Integrated Circuit (IC) chips and more particularly to integrated circuit chips with discrete on-chip capacitors.

2. Background Description

Integrated Circuits (ICs) are commonly made in the well-known complementary insulated gate Field Effect Transistor (FET) technology known as CMOS. Typical high performance ICs include CMOS devices (FETs) formed in a number of stacked layers (e.g., wiring, via, gate and gate dielectric) on a surface semiconductor (silicon) layer of a Silicon On Insulator (SOI) chip or wafer. CMOS technology and chip manufacturing advances have resulted in a steady decrease of chip feature size to increase on-chip circuit switching frequency (circuit performance) and the number of transistors (circuit density). In what is typically referred to as scaling, device or FET features are shrunk to shrink corresponding device minimum dimensions, including both horizontal dimensions (e.g., minimum channel length) and vertical dimensions, e.g., channel layer depth, gate dielectric thickness, junction depths and etc. Shrinking device size increases device density and improves circuit performance (both from increased device drive capability and decreased capacitive load). Scaling also entails thinning the surface device layer to control device threshold roll off. Especially in Ultra-Thin SOI (UTSOI), thinning the surface device layer has resulted in devices with fully depleted bodies (i.e., in what is known as Fully Depleted SOI or FD-SOI). Scaled FD-SOI devices can have substantially higher series resistance, as well as substantially higher capacitance.

Typically CMOS circuits drive a nearly, purely capacitive load. So, minimizing load capacitance further improves circuit performance. One way these capacitive loads have been minimized was by minimizing the dielectric constant (k) of insulating materials used to insulate wiring that connects circuit devices and circuits together. Unfortunately, minimizing load capacitances and parasitic circuit capacitances has also minimized discrete capacitors, e.g., formed on adjacent wiring layers. Typical such discrete capacitors have low per unit area capacitance that may vary widely and has very poor tolerance.

Some performance gains may be offset by supply noise. Supply noise can reduce circuit drive (i.e., because the circuit supply is reduced during such a supply spike) and even, under some circumstances, pass through to the output of a quiescent gate to appear that the gate is switching rather than quiescent. Small decoupling capacitors (decaps), which are well known in the art, are small, high-frequency capacitors, placed close to circuits being decoupled to short circuit switching current at the circuit. Unfortunately, the too low per unit capacitance of typical prior art parallel plate capacitors requires either very large are capacitors or accepting inadequate capacitance and so, is unsuitable decoupling capacitors.

Also, high performance (e.g., radio frequency (RF)) analog circuits frequently require discrete capacitors. A typical Voltage Controlled Oscillator (VCO) in a Phase-Locked Loop (PLL) includes capacitors in RC filters to develop and filter a control voltage derived from the output frequency. The RC must have a time constant at least twice the VCO operating frequency for acceptable filtering. Unfortunately again, these prior art parallel plate capacitors are insufficiently dense for RF applications because of a low per unit area capacitance to be useful.

Thus, there is a need for on-chip capacitors suitable for decoupling and RF analog circuit applications and more particularly, for smaller, denser discrete on-chip capacitors for use in such applications.

### SUMMARY OF THE INVENTION

It is therefore a purpose of the invention to reduce on-chip supply noise;

It is another purpose of the invention to reduce IC on-chip capacitor size;

It is another purpose of the invention to minimize IC on-chip capacitor size.

The present invention is related to an Integrated Circuit (IC) chip with one or more vertical plate capacitors, each vertical plate capacitor connected to circuits on the IC chip and a method of making the chip capacitors. The vertical plate capacitors are formed with base plate pattern (e.g., damascene copper) on a circuit layer and at least one upper plate layer (e.g., dual damascene copper) above, connected to and substantially identical with the base plate pattern. A vertical pair of capacitor plates are formed by the plate layer and base plate. Capacitor dielectric between the vertical pair of capacitor plates is, at least in part, a high-k dielectric.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows a first example of fabricating Vertical Parallel Plate (VPP) capacitors according to a preferred embodiment of the present invention

FIGS. 2A-B shows a cross sectional example of the step of defining capacitor locations in formation of VPP capacitors.

FIGS. 3A-C show a cross sectional example of the step of defining capacitor plate pattern in capacitor locations.

FIGS. 4A-B shows iteratively forming vertical capacitor plates, layer upon layer until the desired capacitance and vertical plate height is achieved.

FIGS. 5A-B show a cross sectional example of the step of defining first alternate preferred embodiment capacitor locations.

FIGS. 6A-B a high-k dielectric layer is formed on the patterned ILD layer and patterned such that high-k dielectric remains above lines.

FIGS. 7A-B show forming vertical capacitor plates, e.g., in a typical dual Damascene metal step.

FIGS. 8A-B show a cross sectional example of the step of defining second alternate preferred embodiment capacitor locations.

FIGS. 9A-D show a high-k dielectric layer formed on the partially patterned ILD layer and patterned such that high-k dielectric fills the pattern.

FIGS. 10A-B show forming vertical capacitor plates after forming high-k dielectric in an upper layer, e.g., in a typical dual Damascene metal step.

FIGS. 11A-D show examples of variations of the high-k dielectric pattern in preferred embodiment vertical parallel plate capacitors.

FIGS. 12A-D show a cross sectional example of forming an alternate embodiment vertical plate capacitor according to the present invention.

FIGS. 13A-B show a plan view and a cross sectional view of the alternate embodiment vertical plate capacitor.

FIGS. 14A-D show a cross sectional example of a variation of the alternate embodiment vertical plate capacitor.

### DESCRIPTION OF PREFERRED EMBODIMENTS

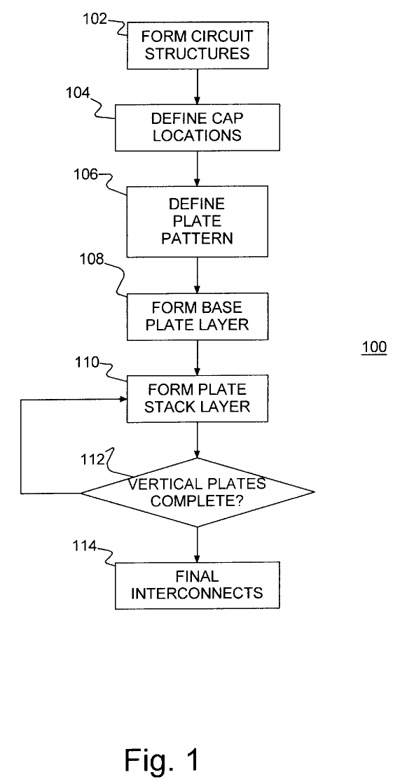

Turning now to the drawings, and more particularly, FIG. 1 shows a first example of fabricating Vertical Parallel Plate (VPP) capacitors according to a preferred embodiment of the present invention. The capacitor formation begins in step 102 in a wiring layer after typical circuit structure formation on a semiconductor wafer, e.g., after device formation and forming an initial inter-layer dielectric (ILD) layer on the devices. In step 104 capacitor locations are defined e.g., by forming a capacitor dielectric base on the ILD layer. Preferably, the capacitor dielectric base is a high-k dielectric material. In step 106 a capacitor plate pattern is defined, e.g., forming wiring layer dielectric on the patterned capacitor dielectric base, patterning the wiring layer dielectric and capacitor dielectric base, and in step 108 filling with conductive material, preferably metal. The capacitor plate pattern defines a base for the vertical plane placement in the capacitor dielectric base and dielectric layer. Preferably, the base capacitor plate pattern is an inter-digitated comb structure. Having defined the capacitor plate pattern, plates are iteratively extended vertically, layer by layer, adding a layer in step 110 until in step 112 the desired plate width is achieved, i.e., the vertical plate height is a desired number of layers. In the examples described herein, the vertical plates are formed in a single iteration with a base pattern and an upper pattern layer with connection through an ILD layer therebetween and high-k dielectric occupying at least a portion of the volume between the vertical plates (i.e., the capacitor dielectric at least includes high-k dielectric) for further increased capacitance. Finally, in step 114 the final chip connections are formed, e.g., off chip pads, chip passivation and solder balls.

Thus, preferred embodiment VPP capacitors may be formed in Integrated Circuits (ICs) fabricated in any technology. In particular, preferred embodiment VPP capacitors may be formed in the well-known complementary insulated gate Field Effect Transistor (FET) technology known as CMOS in a number of stacked layers above circuits formed on a surface semiconductor (silicon) layer of a Silicon On Insulator (SOI) chip or wafer. Moreover, preferred embodiment VPP capacitors in Ultra-Thin SOI (UTSOI) for use in what is known as Fully Depleted SOI or FD-SOI have substantially higher per unit capacitance for significantly denser capacitors.

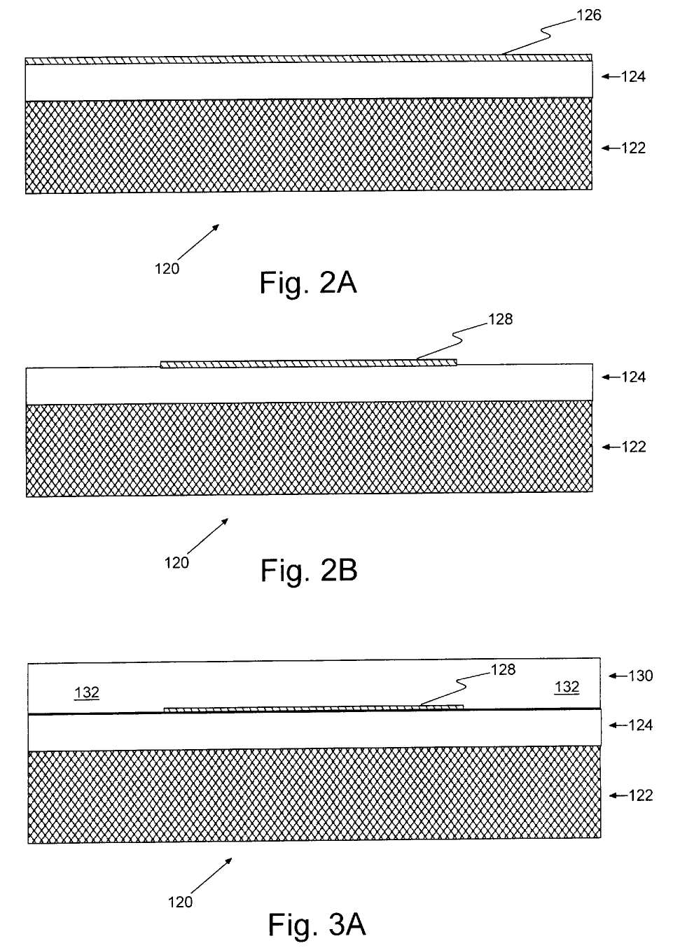

FIGS. 2A-B shows a cross sectional example of defining capacitor locations (e.g., step 104 in FIG. 1) in formation of VPP capacitors according to a preferred embodiment of the present invention. After forming devices (e.g., Field Effect Transistors (FETs)) in chip locations on a wafer 120, e.g., a SOI wafer, and connecting the devices into circuits or circuit elements in layer 122 (in step 102 of FIG. 1), a first ILD layer 124 may be formed on the circuit structure layer 122. It should be noted that, although described herein as VPP capacitors being formed above the circuit structure layer 122 and first ILD layer 124, this is for example only and not intended as a limitation. Preferred VPP capacitors may be formed anywhere in IC chip formation, e.g., beginning at initial device interconnect levels. A high-k dielectric material layer 126 is formed on the first ILD layer 124 and patterned, e.g., photolithographically, to define a capacitor location 128. The high-k dielectric material layer 126 may be a 0.05-0.2 micrometer (μm or micron) thick layer of any suitable high-k dielectric, such as, for example, N-blok (SiCN), silicon nitride (SiN), tantalum pentoxide (Ta₂O₅) or hafnium dioxide (HfO₂).

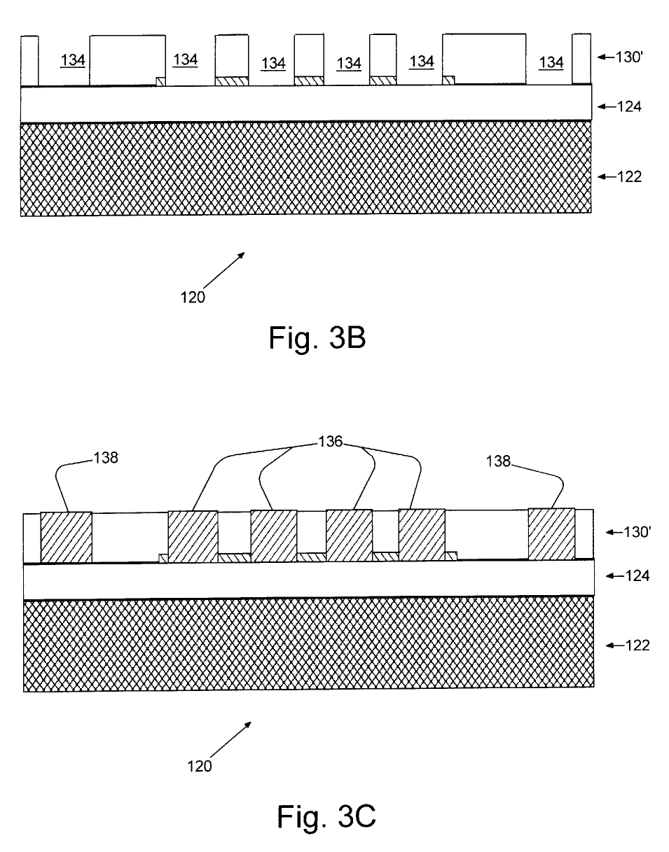

FIGS. 3A-C show a cross sectional example of the next step of defining capacitor plate pattern (e.g., 106 in FIG. 1) in capacitor locations 128. A dielectric layer 130 is formed on the wafer 120, covering both the capacitor locations 128 and previously exposed areas 132 of first dielectric layer 124, i.e., surrounding capacitor locations 128. Preferably, the dielectric layer 130 is a 0.4-2.0 μm thick layer of a low-k dielectric, such as for example, silicon oxycarbide (SiCOH), FluoroSilicate Glass (FSG), TetraEthylOrthoSilicate (TEOS) or Fluorine-doped TEOS (FTEOS). Next, using a typical, suitable patterning technique, e.g., photolithographically masking and etching, the dielectric layer 130 is patterned 134, such that the capacitor plate pattern is formed in the capacitor locations 128 and in non-capacitor areas 132, preferably coincidentally, for a Faraday cage. Preferably, the dielectric material layer 130 and high-k material defining capacitor locations 128 are etched in a two step etching step, using an etchant that is selective to the high-k dielectric to remove portions of the dielectric layer 130 above high-k material; followed by a second etchant that is selective to the dielectric layer 130 to remove exposed high-k dielectric. The patterned dielectric layer 130′ is filled with a conductive material such as metal. Preferably, in a typical damascene step, the patterned dielectric layer 130′ is filled with copper and the wafer is planarized, e.g., using a typical chemical-mechanical polish (chem-mech polish or CMP). After CMP the conductive material 136, 138 remaining in the capacitor plate pattern 134 and non-capacitor areas 132 defines the location of vertical capacitor plates 136 and the Faraday cage 138.

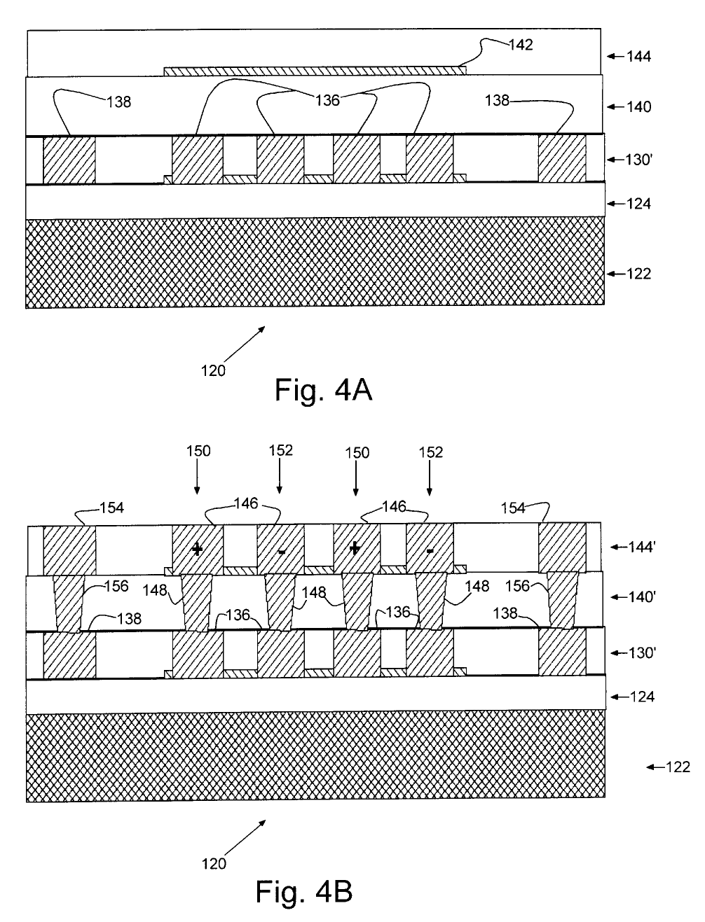

Then for this first embodiment as shown in FIGS. 4A-B, vertical capacitor plates are iteratively formed, layer upon layer, until the desired capacitance and vertical plate height is achieved. Preferably, a typical dual Damascene metal step is used to form each additional plate layer. So, a second ILD layer 140, preferably 0.3-0.7 μm thick, is formed on the base capacitor pattern in patterned dielectric layer 130′. A second high-k dielectric, preferably 0.05-0.2 μm thick, is formed on the second ILD layer 140. The second high-k dielectric is patterned substantially identically to forming the high-k dielectric defining capacitor locations 142, i.e., depositing a high-k dielectric layer and patterning photlithographically. Then, another dielectric layer 144 is formed on the second high-k dielectric 142. The dielectric layer 144 and high-k dielectric 142 are patterned substantially identically to defining the capacitor locations in a two step etch. Once the exposed (through patterned dielectric layer 144′) high-k dielectric 142 has been patterned, through-vias or inter-layer contacts are opened through the underlying second ILD layer 140 to the capacitor plate pattern lines 136, 138. The openings through layers 140′ and 144′ are filled with conductive material, preferably copper, and the wafer is planarized, e.g., using CMP. As a result, lines 146 and vias 148 form vertical plates 150, 152 with conductive lines 136, thereby forming a vertical plate capacitor and lines 154 and vias 156 extend the Faraday cage vertically from lines 138. It should be noted that, although described as vias 148, 156, this is for example only. Trenches may be opened through the underlying second dielectric material layer 140 to the capacitor plate pattern 134, thereby forming metal lines between lines 146 and the capacitor definition lines 138. Once vertical plate formation is complete, in step 114 of FIG. 1 the final chip connections are formed, forming off-chip pads, passivating and forming solder balls on the off-chip pads.

Thus, the capacitance of the vertical plate capacitor is dependent upon and easily determinable from both capacitor dimensions (e.g., plate 150, 152 height, spacing and number of plate 150, 152 fingers) and technology specific parameters, e.g., dielectric constant values of both high-k and low-k. So, capacitance may be increased, for example, by increasing length of the lines 138, 146 that form the plate 150, 152 fingers; increasing the number of plate 150, 152 fingers; and/or increasing the vertical plate height, i.e., by adding Damascene wiring layers.

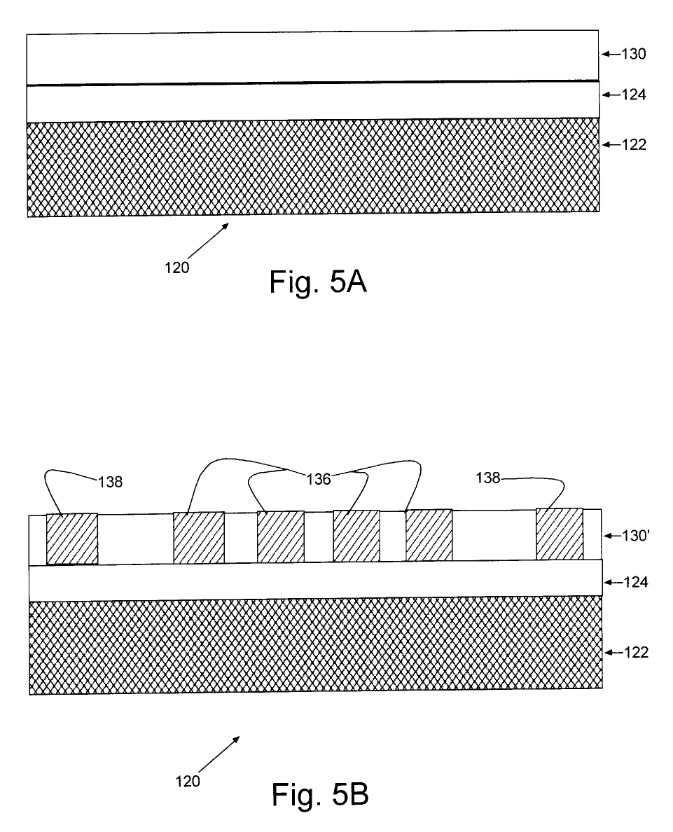

In a first variation on this preferred embodiment, a single high-k dielectric layer is formed on the base plate pattern, i.e., at the bottom of through vias. FIGS. 5A-B show a cross sectional example of the step of defining locations for this first variation of the preferred embodiment capacitor, which is substantially more simple than FIGS. 2A-3C. In this example like elements (with the first variation) are labeled identically. So, in this example, instead of forming the high-k dielectric material layer 126, dielectric layer 130 is formed directly on ILD layer 124. Preferably, the dielectric layer 130 is 0.4-1.0 μm thick. Again, using typical suitable patterning technique, e.g., photolithographically masking and etching, the dielectric layer 130 is patterned and conductive material lines 136, 138 are formed in the patterned dielectric layer 130′. Preferably, the lines 136, 138 are Damascene copper that is deposited to fill the pattern and chem-mech polished to planarize the wafer. Again, lines 136 define plate fingers.

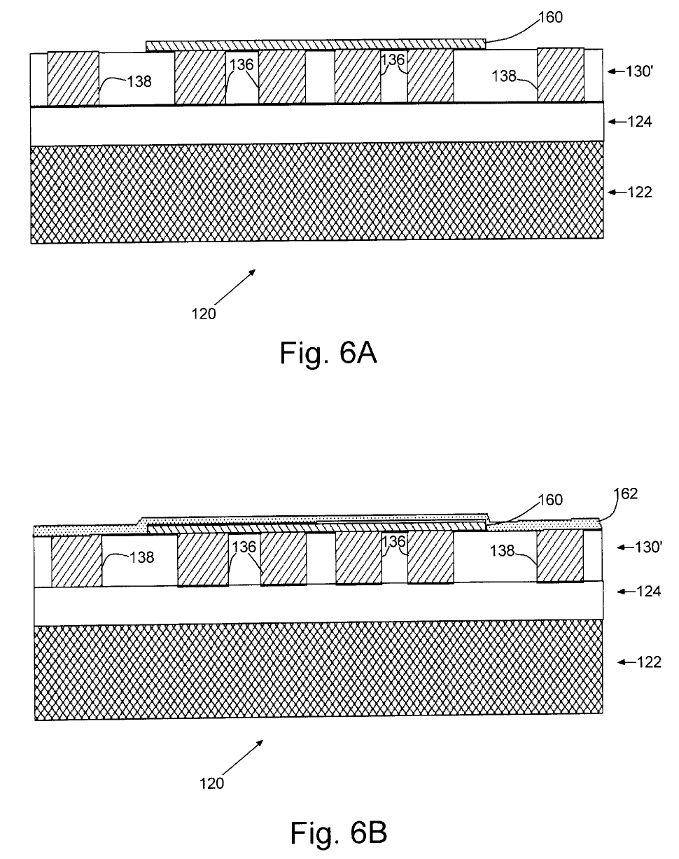

Next, as shown in FIGS. 6A-B a high-k dielectric layer 160 is formed on the patterned dielectric layer 130′ and patterned such that high-k dielectric 160 remains above lines 136. Then, a capping layer 162 is formed on the wafer, capping remaining high-k dielectric 160. Preferably, the high-k dielectric layer 160 is a 0.05-0.2 μm thick layer of a suitable high-k dielectric (e.g., N-blok, SiN, Ta₂O₅ or HfO₂) and the capping layer 162 is a 0.03-0.07 μm thick layer of SiCN or SiN.

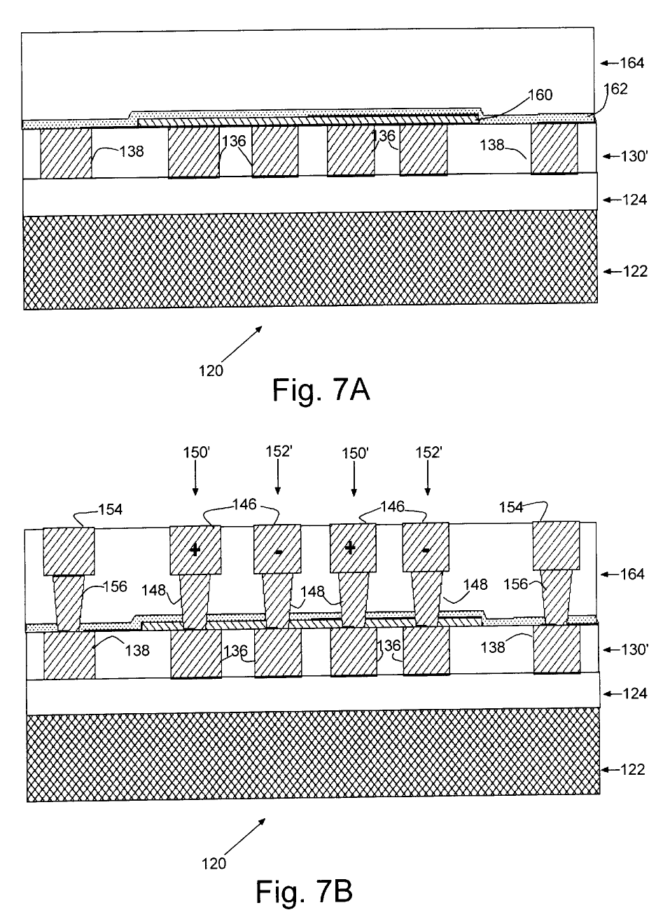

Finally, as shown in FIGS. 7A-B, vertical capacitor plates are formed, again preferably, in a typical dual Damascene metal step. So, a second ILD/wiring dielectric layer 164, preferably a 0.5-2.0 μm thick oxide layer, is formed on capping layer 162. The second ILD/wiring dielectric layer 164 is patterned to the capacitor plate pattern lines 136, 138, substantially identically as described for layers 140′, 144′ of FIGS. 4A-B. As a result, lines 146 and vias 148 form vertical plates 150′, 152′ with conductive lines 136, thereby forming a vertical plate capacitor and lines 154 and vias 156 extend the Faraday cage vertically from lines 138.

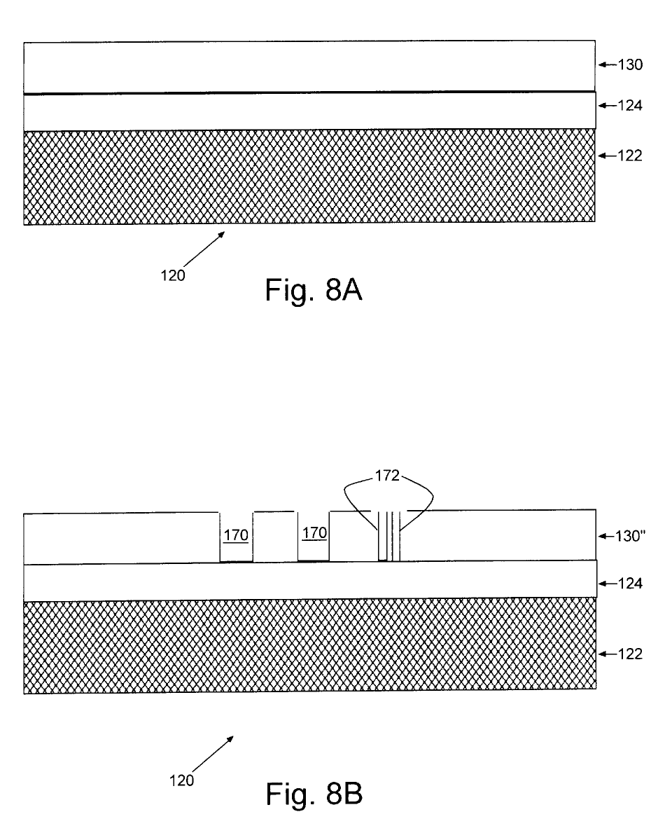

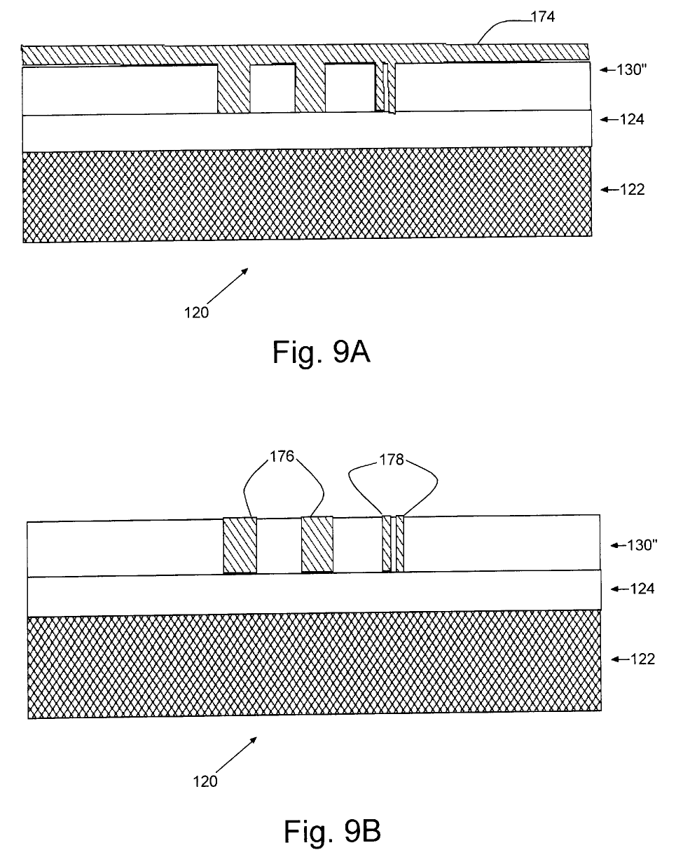

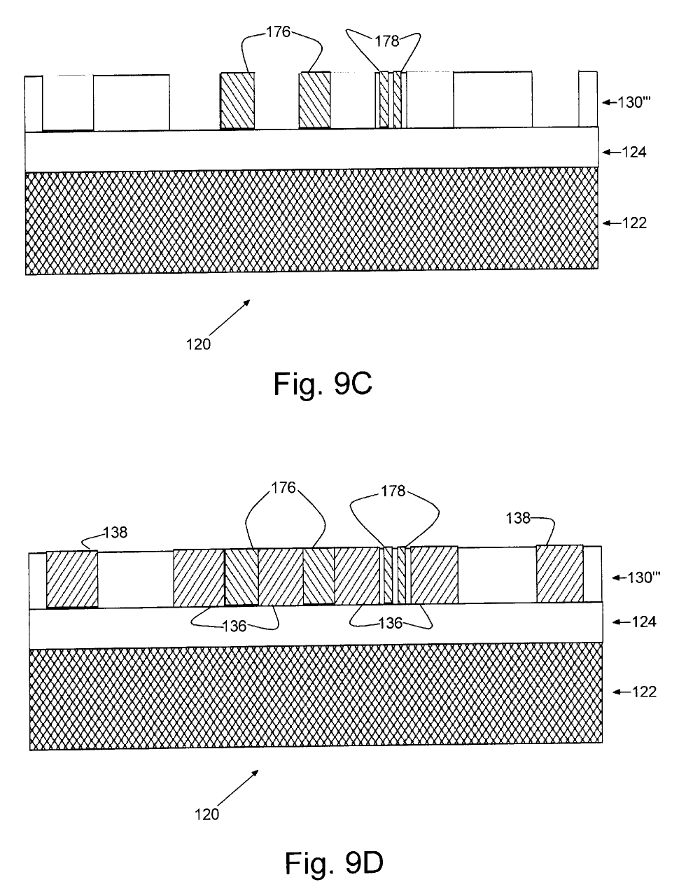

In a second variation on the above preferred embodiment, high-k dielectric substantially replaces lower k material between plate wires in both the base plate layer and the upper wiring layer. So, FIGS. 8A-B show a cross sectional example of the step of defining these second capacitor variation locations, substantially similarly to FIGS. 2A-3C with like elements labeled identically. Again the high-k dielectric material layer 126 is not formed in this example. Instead, preferably, a 0.4-1.0 μm thick dielectric layer is formed directly on ILD layer 124. Again, using typical suitable patterning technique, e.g., photolithographically masking and etching, the dielectric layer 130 is partially patterned. However, in this example, the resulting partial pattern 170, 172, defines high-k dielectric replacement locations in the patterned ILD layer 130″.

So, as shown in FIGS. 9A-D a high-k dielectric layer 174 is formed on the partially patterned ILD layer 130″ and excess high-k is removed such that high-k dielectric 176, 178 fills the pattern (i.e., 170, 172 in FIG. 8B). The high-k dielectric layer 174 may be any suitable high-k dielectric (e.g., N-blok, SiN, Ta₂O₅ or HfO₂) material. Then, the wafer is planarized, preferably using a chem-mech polish, to remove excess high-k dielectric from the wafer surface such that only high-k dielectric plugs 176, 178 remain. Having formed high-k dielectric plugs 176, 178, the partially patterned ILD layer 130″ is further patterned. The lines 136, 138, are formed in the patterned ILD layer 130′″, e.g., in a typical Damascene copper step, depositing copper to fill the pattern and chem-mech polishing to planarize the wafer. Again, lines 136 define plate fingers. It should be noted that high-k dielectric plugs 176, 178 show variations on dielectric filling between plates with plates 136 separated by a uniform high-k dielectric 176 or a partial or interrupted high-k dielectric 176.

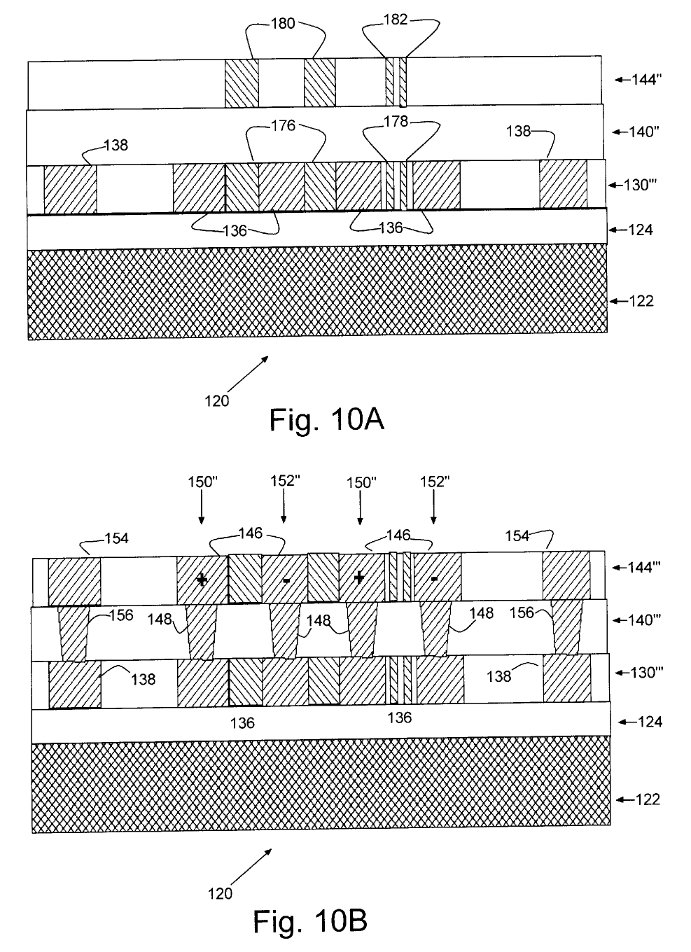

Finally in this preferred embodiment variation, as shown in FIGS. 10A-B, after forming high-k dielectric in an upper layer, vertical capacitor plates are formed, again preferably, in a typical dual Damascene metal step. So, a second ILD layer 140″, preferably a 0.3-0.7 μm thick oxide layer, is formed on the base capacitor pattern in ILD layer 130′″. Also, a second dielectric material layer 144″ is formed on the second ILD layer 140″. The second dielectric layer 144″ is partially patterned substantially identically to partially patterning ILD layer 130″ and high-k dielectric 180, 182 is also formed substantially identically to forming high-k dielectric 176, 178. Having defined high-k dielectric 180, 182 in this upper layer 144″, lines 146 in upper layer 144′″ and vias 148 are formed in ILD layer 140′″ to define vertical plates 150″, 152″ with conductive lines 136, thereby forming a vertical plate capacitor, substantially as described for FIGS. 4B and 7B hereinabove. Likewise, lines 154 and vias 156 form to extend the Faraday cage vertically from lines 138.

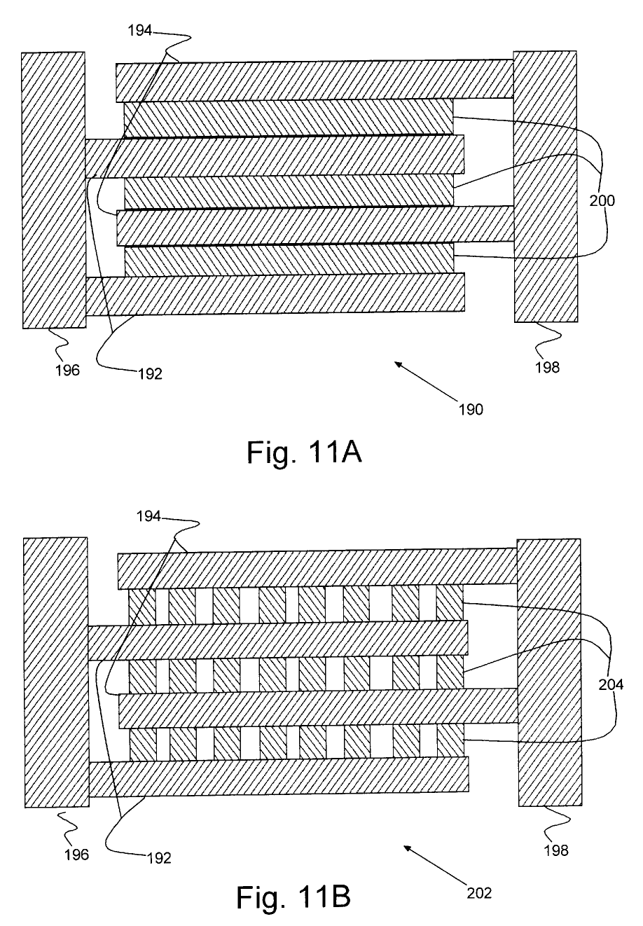

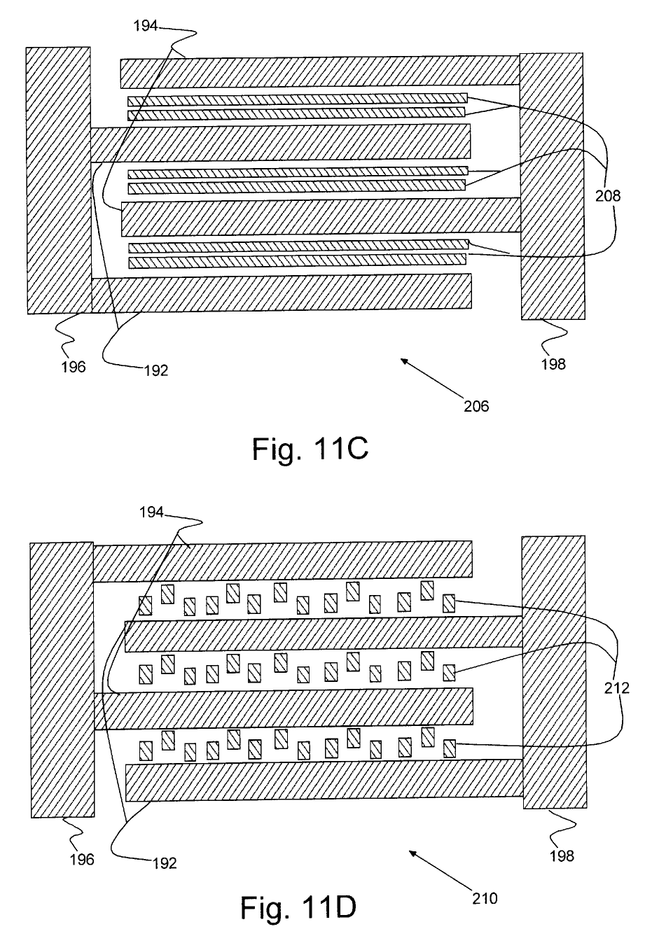

FIGS. 11A-D show examples of variations of high-k dielectric pattern in preferred embodiment vertical parallel plate capacitors, regardless of dielectric thickness, e.g., partially filling the layer as in the examples of FIGS. 4B and 7B or completely as in the example of FIG. 10B. The capacitor 190 includes two (2) pair of interdigitated plate fingers 192, 194 corresponding to 150/150′/150″ and 152/152′/152″ of FIGS. 2A-10B above. Each pair of plate fingers 192, 194 is connected to a common electrode 196, 198. Thus, these examples may be top views of layers 130′/140′ in FIG. 4B, 164 in FIG. 7B, or 130′″/144′″ in FIG. 10B. So, in the example of FIG. 11A, the high-k dielectric 200 is continuous along the length of parallel sections of plate fingers 192, 194 and fills the space therebetween. In the example of FIG. 11B, the capacitor 202 includes high-k dielectric 204 that is discontinuous along the length of parallel sections of plate fingers 192, 194, but fills the space therebetween. In the example of FIG. 11C, the capacitor 206 includes high-k dielectric that is continuous along the length of parallel sections of plate fingers 192, 194, but only partially fills the space therebetween, in this example as pairs of high-k dielectric fingers 208. In the example of FIG. 11D, the capacitor 210 includes high-k dielectric pockets 212 that are distributed along the length of parallel sections of plate fingers 192, 194, and only partially fill the space therebetween.

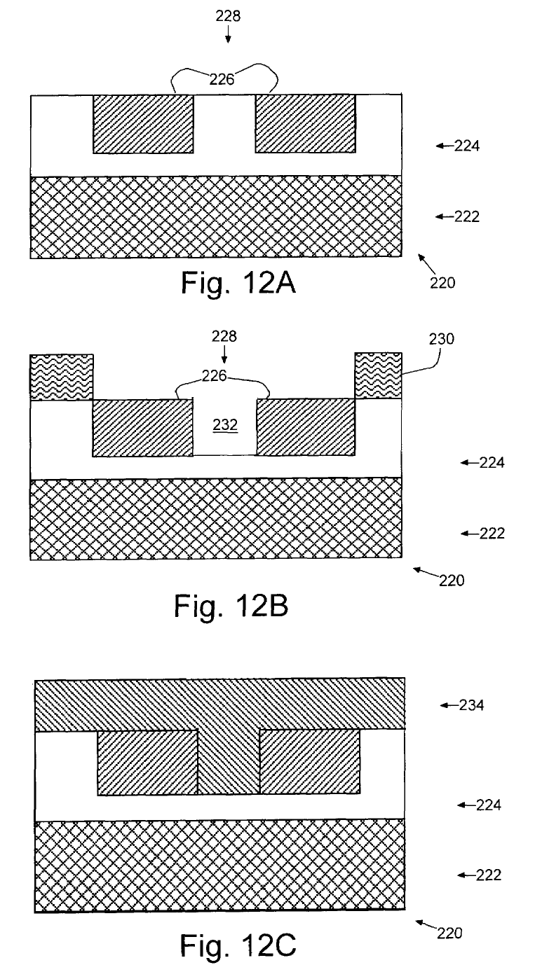

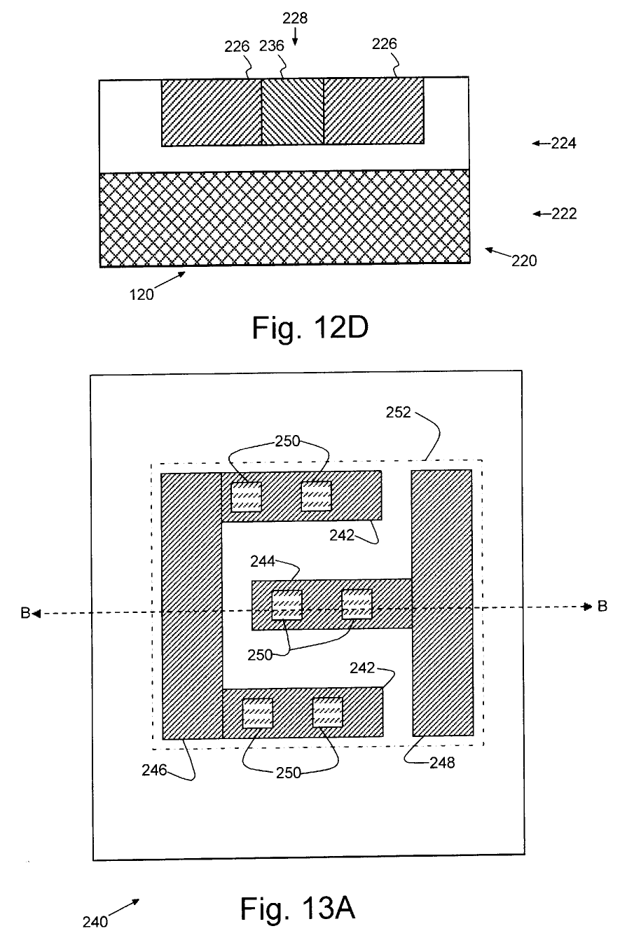

FIGS. 12A-D show a cross sectional example of forming an alternate embodiment vertical plate capacitor according to the present invention. In this embodiment, the metal plate fingers or finger segments are formed first and high-k dielectric is formed between the fingers. So, again, after forming devices in chip locations on a wafer 220, e.g., a SOI wafer, and connecting the devices into circuits or circuit elements in layer 222 (in step 102 of FIG. 1), a first ILD (undoped silicon-glass (USG)/FSG/low k) layer 224 may be formed on the circuit structure layer 222. Wires 226 are formed to define capacitor locations 228 in steps 104 and 106. Preferably, the wires are copper wires formed using a typical Damascene wire formation step. Next, a mask 230 is formed, masking the wafer with capacitor locations 228 remaining exposed. Then, the dielectric is removed between plate finger wires 226, e.g., etching selective to copper, which leaves voids 232 between the plate finger wires 226. The mask 230 is removed and a high-k dielectric material layer 234 is formed on the wafer 220. Again, the high-k dielectric material layer 234 may be of any suitable high-k dielectric, such as, for example, N-blok, SiN, Ta₂O₅ or HfO₂. The wafer 220 is planarized, e.g., chem-mech polished and stopping on the underlying USG/FSG/low k dielectric, to remove excess high-k dielectric material layer 234 such that only plugs 236 of high-k dielectric material remain between the plate finger wires 226. One or more layers of plate finger wires (not shown) may be formed above these first plate finger wires 226, the dielectric removed between the fingers and the resulting voids filled with high-k dielectric material substantially as described for these first plate finger wires 226 until the desired plate height is achieved.

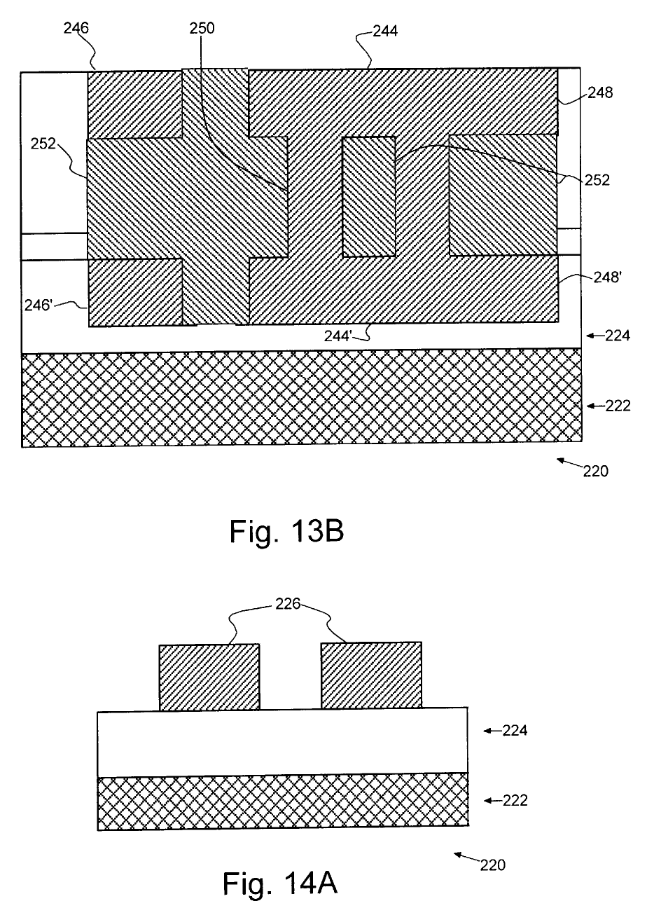

FIGS. 13A-B show a plan view of a preferred capacitor 240 formed as described for the alternate embodiment of FIGS. 12A-D and a cross section of the capacitor 240 through B-B. This capacitor 240 includes a pair of plate fingers 242 separated by a third opposite plate finger 244. The pair of plate fingers 242 are connected to a common electrode 246 and the opposite plate finger 244 is connected to electrode 248. Interlevel through-vias 250 connect corresponding plate finger wires 244, 244′ on adjacent layers together. Connection to electrodes 246, 248 may be at either layer, i.e., at 246, 248 or 246′, 248′. The entire volume not occupied by copper wires or through vias is high-k dielectric 252.

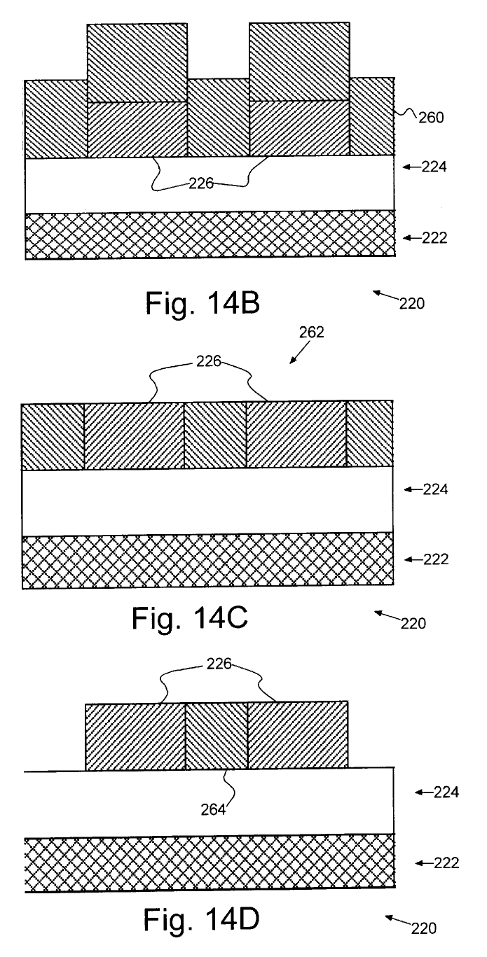

FIGS. 14A-D show a VPP capacitor variation on the cross sectional example of FIGS. 12A-D with like elements labeled identically. In this example, after forming wires 226 on the ILD layer 224 above circuit layer 222 of wafer 220, the dielectric (not shown) in which the wires 226 are formed is removed. Then, a conformal layer of high-k dielectric 260 is formed on the wafer and planarized, e.g., using chem-mech polish and stopping on the metal wires 226. After planarization the capacitor locations 262 are masked (not shown) and the wafer is etched with an etchant that is selective to USG/FSG/low k dielectric layer 224. The mask is removed and high-k dielectric 264 remains only between the plate finger wires 226. Thereafter, a low k dielectric (not shown) may be deposited and planarized and vertical plates may be iteratively formed, layer by layer repeating the steps of FIGS. 14A-D.

Advantageously, preferred embodiment VPP capacitors may be formed in Integrated Circuits (ICs) fabricated in any technology where chip real estate is a premium and small, dense capacitors are needed. In particular, preferred embodiment VPP capacitors may be formed in CMOS circuits in a number of stacked layers (two or more) above circuits including on SOI chips or wafers including UTSOI chips for FD-SOI circuits.

While the invention has been described in terms of preferred embodiments, those skilled in the art will recognize that the invention can be practiced with modification within the spirit and scope of the appended claims. It is intended that all such variations and modifications fall within the scope of the appended claims. Examples and drawings are, accordingly, to be regarded as illustrative rather than restrictive.

We claim:

1. A method of forming Integrated Circuit (IC) chips, said method comprising the steps of:
a) defining at least one capacitor location above one or more circuits on a semiconductor substrate;
b) defining a plate pattern in each defined capacitor location;
c) forming a base plate in said defined plate pattern; and
d) forming one or more upper plate layers above said base plate, a vertical pair of capacitor plates being formed by said base plate and said one or more plate layers, at least a portion of capacitor dielectric between said vertical pair being a high-k dielectric.

2. A method as in claim 1, wherein the step (b) of defining said plate pattern defines a first plate on either side of a second plate.

3. A method as in claim 2, wherein each of the step (c) of forming said plate pattern and the step (d) of forming one or more plate layers further comprises replacing dielectric between said first plate and said second plate with high-k dielectric.

4. A method as in claim 2, wherein the step (b) of defining said plate pattern defines two pair of interdigitated plates.

5. A method as in claim 4, wherein the step (a) of defining capacitor locations comprises the steps of:
i) forming a high-k dielectric layer on said semiconductor substrate;
ii) patterning said high-k dielectric layer, the patterned said high-k dielectric layer defining capacitor locations; and
iii) forming a dielectric layer on said patterned high-k dielectric layer, said plate pattern being defined in step (b) through said dielectric layer and said patterned high-k dielectric layer.

6. A method as in claim 5, wherein the step (d) of forming plate layers above the base plate comprises the steps of:
i) forming an InterLevel Dielectric (ILD) layer on said base plate;
ii) forming a second high-k dielectric layer on said ILD layer;
iii) patterning said second high-k dielectric layer; and
iv) forming a second said plate layer through patterned second high-k dielectric layer and forming connections through said ILD layer to said base plate.

7. A method as in claim 4, wherein the capacitor locations defined in step (a) are defined coincident with the step (b) of defining said plate pattern and comprises forming said plate pattern in a dielectric layer on said semiconductor substrate.

8. A method as in claim 7, wherein the step (c) of forming a base plate comprises the steps of:
i) forming said base plate according to said plate pattern;
ii) forming a high-k dielectric layer on said base plate; and
iii) patterning said patterned high-k dielectric layer, said one or more upper plate layers being formed in step (d) being connected to said base plate through said patterned high-k dielectric layer.

9. A method as in claim 8, wherein the step (c) of forming said base plate further comprises:
iv) forming a cap layer on said patterned high-k dielectric layer.

10. A method as in claim 1, wherein the step (d) of forming said one or more upper plate layers comprises a dual damascene patterning step.

11. An Integrated Circuit (IC) chip comprising:
a plurality of circuits in a circuit layer; and
a plurality of vertical plate capacitors above said circuit layer, each vertical plate capacitor connected to one or more of said plurality of circuits, said each vertical plate capacitor comprising:
a base plate pattern in a first dielectric layer,
at least one upper plate layer above and substantially identical with said base plate pattern, a vertical pair of capacitor plates being formed by connection of said at least one plate layer to said base plate, and
a capacitor dielectric between said vertical pair of capacitor plates, at least a portion of said capacitor dielectric being a high-k dielectric.

12. An IC chip as in claim 11, wherein said capacitor dielectric is said high-k dielectric.

13. An IC chip as in claim 11, wherein said vertical pair of capacitor plates comprise:
two pair of interdigitated vertical plates;
a first electrode connecting a first pair together; and
a second electrode connecting a first pair together, said one or more of said plurality of circuits being connected at said first electrode and said second electrode.

14. An IC chip as in claim 13, wherein said at least one upper plate layer is one upper plate layer and said capacitor dielectric comprises:
a first layer of said high-k dielectric between said two pair of interdigitated vertical plates at a bottom of said two pair; and
a second layer of said high-k dielectric between said two pair of interdigitated vertical plates at a bottom of said one upper plate layer.

15. An IC chip as in claim 14, wherein capacitor dielectric between said two pair in said base plate pattern is said first layer of high-k dielectric and in said one upper plate layer is said second layer of high-k dielectric.

16. An IC chip as in claim 13, wherein said at least one upper plate layer is one upper plate layer and said capacitor dielectric comprises:
a layer of said high-k dielectric between said two pair of interdigitated vertical plates at a top of said base plate pattern; and
a capping layer on said layer of high-k dielectric.

17. An IC chip as in claim 11, wherein said high-k dielectric is discontinuous along the length of parallel sections of plate fingers.

18. An IC chip as in claim 17, wherein discontinuous said high-k dielectric sections extend the distance between said parallel sections of plate fingers.

19. An IC chip as in claim 11, wherein said high-k dielectric is in pairs of continuous high-k dielectric fingers along the length of parallel sections of plate fingers.

20. An IC chip as in claim 11, wherein said high-k dielectric is selected from the group consisting of N-blok (SiCN), silicon nitride (SiN), tantalum pentoxide (Ta₂O₅) or hafnium dioxide (HfO₂).
